(19) United States
(12) Patent Application Publication
(10) Pub. No.: US 2022/0375847 A1
(43) Pub. Date: Nov. 24, 2022

(54) SEMICONDUCTOR DEVICES INCLUDING GATE STRUCTURE AND METHOD OF FORMING THE SAME

(71) Applicant: SAMSUNG ELECTRONICS CO., LTD., Suwon-si (KR)

(72) Inventor: Sungmin Kim, Incheon (KR)

(21) Appl. No.: 17/453,538

(22) Filed: Nov. 4, 2021

(30) Foreign Application Priority Data
May 24, 2021 (KR) 10-2021-0065972

(51) Int. Cl. H01L 23/522; H01L 29/66; H01L 29/78; H01L 29/786; H01L 23/528; H01L 21/768

(52) U.S. Cl. CPC H01L 23/522; H01L 29/66545; H01L 29/785; H01L 29/78696; H01L 23/5283; H01L 21/76885; H01L 29/42392

(57) ABSTRACT

A semiconductor device includes an active region defined on a substrate. A lower gate structure is disposed on the active region and crosses the active region. An upper gate structure is disposed on the lower gate structure and has a width that differs from a width of the lower gate structure. A pair of source/drain regions are disposed in the active region adjacent to opposite sides of the lower gate structure. A center of the upper gate structure is offset from a center of the lower gate structure.

### CROSS-REFERENCE TO THE RELATED APPLICATION

This non-provisional application claims priority under 35 U.S.C. § 119 from Korean Patent Application No. 10-2021-0065972, filed on May 24, 2021 in the Korean Intellectual Property Office, the contents of which are herein incorporated by reference in their entirety.

### TECHNICAL FIELD

Exemplary embodiments of the disclosure are directed to semiconductor devices that include a gate structure and a method of forming the same.

### DISCUSSION OF THE RELATED ART

As semiconductor devices become more highly integrated, the aspect ratio of a gate electrode has gradually increased. For example, a sacrificial gate electrode that intersects a fin active region may be disposed on the fin active region. Trenches are formed by recessing the fin active region at opposite sides of the sacrificial gate electrode. Source/drain regions are formed in the trenches using an epitaxial growth method. The sacrificial gate electrode is removed, and a replacement metal gate electrode is formed.

An increase in the aspect ratio of a sacrificial gate electrode may be advantageous in terms of securing current drivability and high integration. However, an increase in the aspect ratio of the gate electrode may cause various process failures. For example, an increase in the aspect ratio of the sacrificial gate electrode may cause various failures such as leaning, sidewall roughness, and/or physical distribution increase of trenches. In addition, the patterning process that forms a gate electrode is becoming more challenging, and controlling depth and shape of source/drain regions is also becoming more challenging.

### SUMMARY

Exemplary embodiments of the disclosure provide semiconductor devices that have excellent electrical characteristics and can be efficiently mass-produced, and formation methods thereof.

A semiconductor device according to exemplary embodiments of the disclosure includes an active region defined on a substrate. A lower gate structure is disposed on the active region and crosses the active region. An upper gate structure is disposed on the lower gate structure and has a width that differs from a width of the lower gate structure. A pair of source/drain regions are disposed in the active region adjacent to opposite sides of the lower gate structure. A center of the upper gate structure is disposed to be offset from a center of the lower gate structure.

A semiconductor device according to exemplary embodiments of the disclosure includes a plurality of active regions that are vertically aligned on a substrate. A lower gate structure is disposed on the plurality of active regions, crosses the plurality of active regions and surrounds a top surface, a bottom surface and side surfaces of at least one of the plurality of active regions. An upper gate structure is disposed on the lower gate structure and has a width that differs from a width of the lower gate structure. A pair of source/drain regions are disposed adjacent to opposite sides of the lower gate structure while contacting the plurality of active regions. A center of the upper gate structure is offset from a center of the lower gate structure.

A semiconductor device according to exemplary embodiments of the disclosure includes an active region defined on a substrate. A lower gate structure is disposed on the active region and crosses the active region. An upper gate structure is disposed on the lower gate structure and has a width that differs from a width of the lower gate structure. A pair of source/drain regions are disposed in the active region adjacent to opposite sides of the lower gate structure. A center of the upper gate structure is offset from a center of the lower gate structure. The lower gate structure includes a pair of lower spacers that oppose each other, and a lower gate electrode interposed between the pair of lower spacers. The upper gate structure includes an upper gate electrode disposed on the lower gate electrode, and a capping layer disposed on the upper gate electrode.

A method for forming a semiconductor device in accordance with exemplary embodiments of the disclosure includes providing an active region defined on a substrate. A lower gate structure that crosses the active region is formed on the active region. An upper gate structure is formed on the lower gate structure. The upper gate structure has a width that differs from a width of the lower gate structure, and a center of the upper gate structure is offset from a center of the lower gate structure. A pair of source/drain regions is formed in the active region adjacent to opposite sides of the lower gate structure.

### BRIEF DESCRIPTION OF THE DRAWINGS

FIG. 1 shows cross-sectional views of a semiconductor device according to exemplary embodiments of the disclosure.

FIGS. 2 to 8 are partial views that show a portion 5 of FIG. 1.

FIG. 9 shows cross-sectional views of a semiconductor device according to exemplary embodiments of the disclosure.

FIGS. 10 to 12 are partial views that show a portion 6 of FIG. 9.

FIGS. 13 and 14 are cross-sectional views of semiconductor devices according to exemplary embodiments of the disclosure.

FIGS. 15 to 17 are partial views that show a portion 7 of FIG. 14.

FIG. 18 is a layout of a semiconductor device according to exemplary embodiments of the disclosure.

FIGS. 19 to 39 are cross-sectional views that illustrate methods of forming semiconductor devices according to exemplary embodiments of the disclosure.

### DETAILED DESCRIPTION OF EXEMPLARY EMBODIMENTS

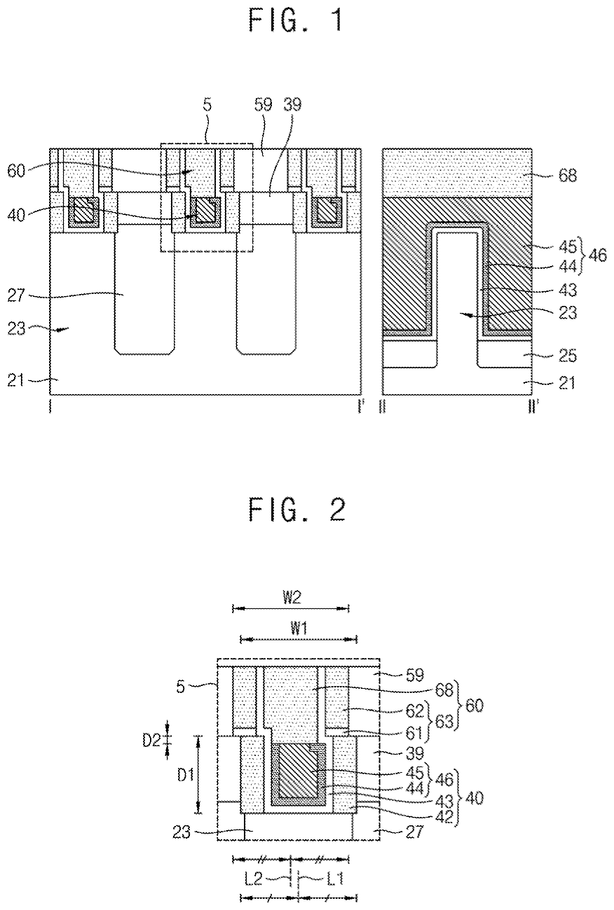

FIG. 1 shows cross-sectional views of a semiconductor device according to exemplary embodiments of the disclosure. FIGS. 2 to 8 are partial views that show a portion 5 of FIG. 1. In an embodiment, FIG. 1 shows cross-sectional views taken along lines I-I′ and II-II′ in FIG. 18. Semiconductor devices according to exemplary embodiments of the disclosure may include a fin field effect transistor (finFET), a multi-bridge channel transistor such as an MBCFET®, a nano-wire transistor, a vertical transistor, a recess channel transistor, a 3-D transistor, a planar transistor, or a combination thereof. In an embodiment, semiconductor devices according to exemplary embodiments of the disclosure include a finFET.

Referring to FIG. 1, semiconductor devices according to exemplary embodiments of the disclosure include a substrate 21, an active region 23, an element isolation layer 25, a plurality of source/drain regions 27, a first interlayer insulating layer 39, a plurality of gate structures 40 and 60, and a second interlayer insulating layer 59. Each of the plurality of gate structures 40 and 60 includes a lower gate structure 40 and an upper gate structure 60.

Referring to FIG. 2, according to exemplary embodiments, the lower gate structure 40 includes a pair of lower spacers 42 that oppose each other, a gate dielectric layer 43, and a gate electrode 46. The gate electrode 46 includes a first layer 44 and a second layer 45. The upper gate structure 60 includes a pair of upper spacers 63 that oppose each other, and a capping layer 68. Each of the pair of upper spacers 63 includes a first upper spacer 61 and a second upper spacer 62.

Again referring to FIGS. 1 and 2, according to exemplary embodiments, the active region 23 is defined on the substrate 21 by the element isolation layer 25. The plurality of gate structures 40 and 60 are disposed on the substrate 21 and extend on the element isolation layer 25 and cross the active region 23. The plurality of gate structures 40 and 60 extend in a direction substantially perpendicular to an extension direction of the active region 23. Each of the plurality of gate structures 40 and 60 includes the lower gate structure 40, and the upper gate structure 60 on the lower gate structure 40. A pair of source/drain regions 27 are disposed in the active region 23 adjacent to opposite sides of the lower gate structure 40.

According to exemplary embodiments, the lower gate structure 40 extends on the element isolation layer 25 and covers a top surface and side surfaces of the active region 23. The gate dielectric layer 43 and the gate electrode 46 are disposed between the pair of lower spacers 42. The first layer 44 of the gate electrode 46 surrounds a side surface and a bottom surface of the second layer 45. The gate electrode 46 extends on the element isolation layer 25 and covers the top surface and the side surfaces of the active region 23. A lowermost end of the gate electrode 46 is located at a lower level than the top surface of the active region 23.

According to exemplary embodiments, the gate dielectric layer 43 is disposed between the gate electrode 46 and the active region 23, and extends between the gate electrode 46 and the element isolation layer 25. The gate dielectric layer 43 surrounds a bottom surface and side surfaces of the gate electrode 46. The gate dielectric layer 43 extends between the pair of lower spacers 42 and the gate electrode 46.

According to exemplary embodiments, the upper gate structure 60 vertically overlaps the lower gate structure 40. The capping layer 68 is disposed between the pair of upper spacers 63. The gate dielectric layer 43 extends between the pair of upper spacers 63 and the capping layer 68. Top surfaces of the second interlayer insulating layer 59, the pair of upper spacers 63, the gate dielectric layer 43, and the capping layer 68 are substantially coplanar.

According to exemplary embodiments, the upper gate structure 60 has a different width from the lower gate structure 40. The lower gate structure 40 has a first width W1. The upper gate structure 60 has a second width W2. In an embodiment, the second width W2 is less than the first width W1. In an embodiment, the second width W2 is greater than the first width W1.

According to exemplary embodiments, the center of the upper gate structure 60 is offset from the center of the lower gate structure 40. Let a first line L1 pass through the center of the lower gate structure 40 while being perpendicular to a surface of the substrate 21. Let a second line L2 pass the center of the upper gate structure 60 while being perpendicular to the surface of the substrate 21. The second line L2 is parallel to the first line L1. The center of the upper gate structure 60 is spaced apart from the first line L1. The center of the lower gate structure 40 is spaced apart from the second line L2. Each of the pair of upper spacers 63 overlaps a top surface of one of the pair of corresponding lower spacers 42. Side surfaces of the pair of upper spacers 63 are not aligned with side surfaces of the pair of lower spacers 42.

According to exemplary embodiments, the capping layer 68 vertically overlaps the gate electrode 46. An interface between the gate electrode 46 and the capping layer 68 is spaced apart from a plane of the interface between the pair of lower spacers 42 and the pair of upper spacers 63.

In an embodiment, the capping layer 68 extends between the pair of lower spacers 42. A lowermost end of the capping layer 68 is closer to the top surface of the substrate 21 than an uppermost end of the pair of lower spacers 42. Each of the pair of lower spacers 42 has a vertical thickness that is greater than a horizontal width thereof. The vertical thickness of each of the pair of lower spacers 42 is a first thickness D1. The distance between the plane of the interface between the pair of lower spacers 42 and the pair of upper spacers 63 and the lowermost end of the capping layer 68 is a second thickness D2. The second thickness D2 is less than 0.2 times the first thickness D1.

In an embodiment, the second upper spacer 62 is disposed on the first upper spacer 61. The first upper spacer 61 is disposed between the pair of lower spaces 42 and the second upper spacer 62. The horizontal width of the first upper spacer 61 is greater than the vertical height of the first upper spacer 61. The vertical height of the second upper spacer 62 is greater than the horizontal width of the second upper spacer 62. The first upper spacer 61 includes a different material from the pair of lower spacers 42 and the second upper spacer 62.

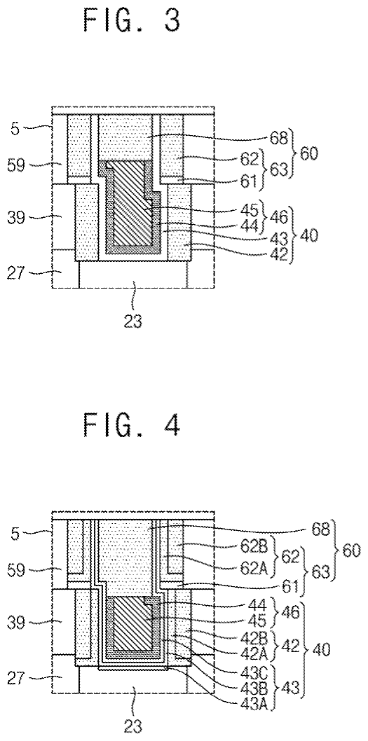

Referring to FIG. 3, the interface between the gate electrode 46 and the capping layer 68 is a higher than the plane of the interface between the pair of lower spacers 42 and the pair of upper spacers 63. In an embodiment, the gate electrode 46 extends between the pair of upper spacers 63. The lowermost end of the capping layer 68 is further from the top surface of the substrate 21 than a lowermost end of the pair of upper spacers 63.

The gate dielectric layer 43 may be a single layer or includes multiple layers. Referring to FIG. 4, in an embodiment, the gate dielectric layer 43 includes a first gate dielectric layer 43A, a second gate dielectric layer 43B, and a third gate dielectric layer 43C that are sequentially stacked. The first gate dielectric layer 43A is disposed between the gate electrode 46 and the active region 23. The first gate dielectric layer 43A directly contacts the active region 23. The first gate dielectric layer 43A includes a silicon oxide layer that is formed using a cleaning process.

In an embodiment, the second gate dielectric layer 43B is disposed between the first gate dielectric layer 43A and the gate electrode 46 and extends between the pair of lower spacers 42 and the gate electrode 46. The second dielectric layer 43B extends between the pair of upper spacers 63 and the capping layer 68. The second gate dielectric layer 43B includes an LaO layer. In an embodiment, the second gate dielectric layer 43B is omitted. The third gate dielectric layer 43C is disposed between the second gate dielectric layer 43B and the gate electrode 46 and extends between the second dielectric layer 43B and the capping layer 68. The third gate dielectric layer 43C includes a high-k dielectric layer such as an HfO layer.

Each of the pair of lower spaces 42 may be a single layer or includes multiple layers. In an embodiment, each of the pair of lower spacers 42 includes an inner lower spacer 42A, and an outer lower spacer 42B on the inner lower spacer 42A. The outer lower spacer 42B may include a different material from the inner lower spacer 42A, or may include the same material as the inner lower spacer 42A. The inner lower spacer 42A has an L shape. The outer lower spacer 42B has a bar shape.

The second upper spacer 62 may be a single layer or includes multiple layers. In an embodiment, the second upper spacer 62 includes an inner upper spacer 62A, and an outer upper spacer 62B on the inner upper spacer 62A. The outer upper spacer 62B may include a different material from the inner upper spacer 62A, or may include the same material as the upper spacer 62A. The inner upper spacer 62A has an L shape. The outer upper spacer 62B has a bar shape.

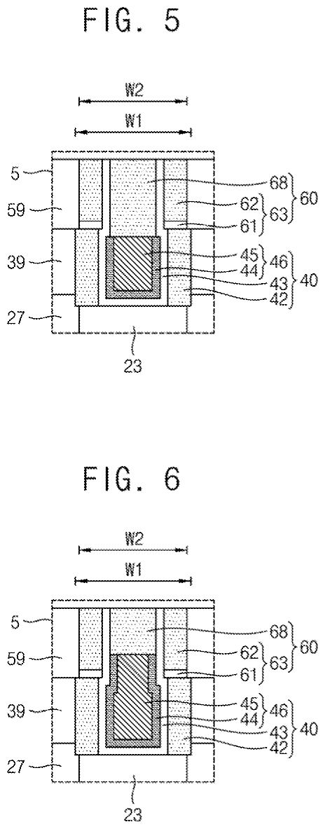

Referring to FIG. 5, in an embodiment, the second width W2 of the upper gate structure 60 is less than the first width W1 of the lower gate structure 40. The interface between the gate electrode 46 and the capping layer 68 is located at a lower level than the plane of the interface between the pair of lower spacers 42 and the pair of upper spacers 63. The center of the upper gate structure 60 is aligned with the center of the lower gate structure 40.

Referring to FIG. 6, in an embodiment, the second width W2 of the upper gate structure 60 is less than the first width W1 of the lower gate structure 40. The interface between the gate electrode 46 and the capping layer 68 is located at a higher level than the plane of the interface between the pair of lower spacers 42 and the pair of upper spacers 63.

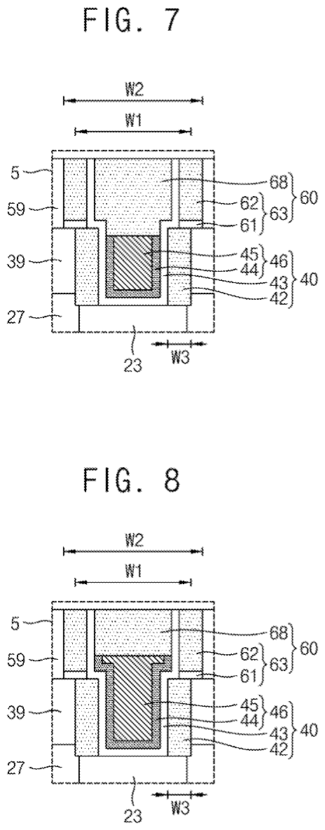

Referring to FIG. 7, in an embodiment, the second width W2 of the upper gate structure 60 is greater than the first width W1 of the lower gate structure 40. Each of the pair of lower spacers 42 has a third width W3. The second width W2 is less than a sum of the third width W3 and the first width W1. The interface between the gate electrode 46 and the capping layer 68 is located at a lower level than the plane of the interface between the pair of lower spacers 42 and the pair of upper spacers 63. The center of the upper gate structure 60 is aligned with the center of the lower gate structure 40.

Referring to FIG. 8, in an embodiment, the second width W2 of the upper gate structure 60 is greater than the first width W1 of the lower gate structure 40. The second width W2 is less than the sum of the third width W3 and the first width W1. The interface between the gate electrode 46 and the capping layer 68 is located at a higher level than the plane of the interface between the pair of lower spacers 42 and the pair of upper spacers 63.

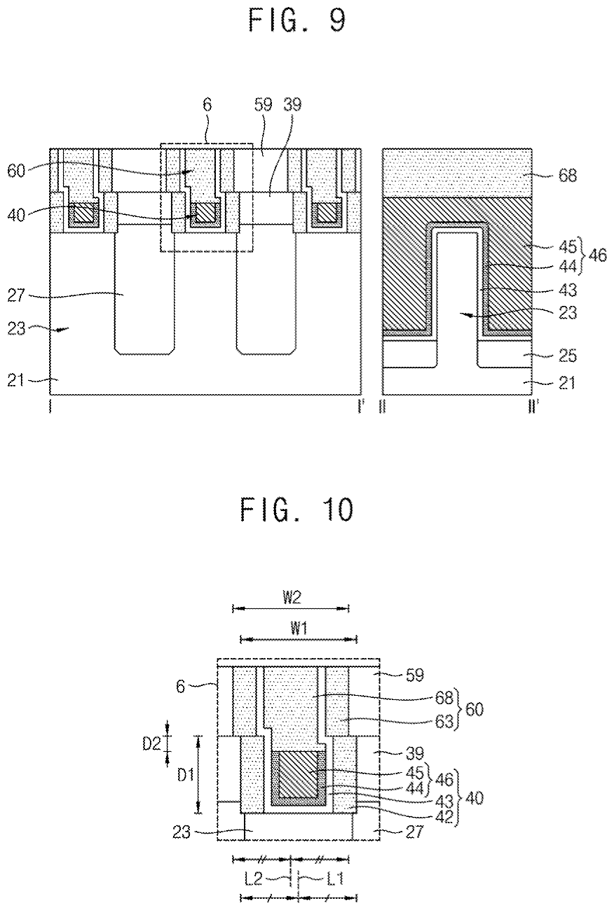

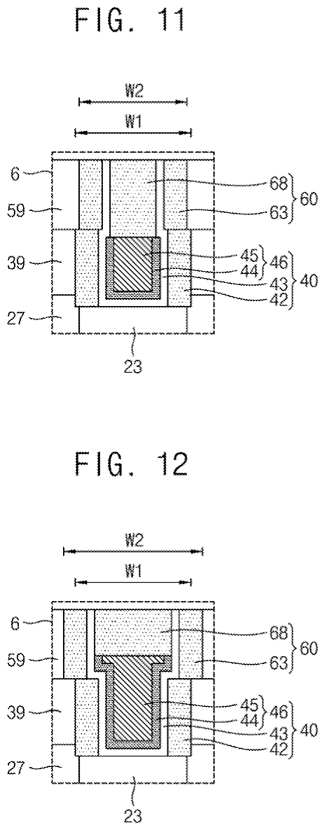

FIG. 9 shows cross-sectional views of a semiconductor device according to exemplary embodiments of the disclosure. FIGS. 10 to 12 are partial views of a portion 6 of FIG. 9. In an embodiment, FIG. 9 shows cross-sectional views taken along lines I-I′ and II-II′ in FIG. 18.

Referring to FIG. 9, semiconductor devices according to exemplary embodiments of the disclosure include a substrate 21, an active region 23, an element isolation layer 25, a plurality of source/drain regions 27, a first interlayer insulating layer 39, a plurality of gate structures 40 and 60, and a second interlayer insulating layer 59. Each of the plurality of gate structures 40 and 60 includes a lower gate structure 40 and an upper gate structure 60.

Referring to FIG. 10, in an embodiment, the lower gate structure 40 includes a pair of lower spacers 42 that oppose each other, a gate dielectric layer 43, and a gate electrode 46. The gate electrode 46 includes a first layer 44 and a second layer 45. The upper gate structure 60 includes a pair of upper spacers 63 that oppose each other, and a capping layer 68. The first upper spacer 61 of FIG. 2 is omitted.

Referring to FIG. 11, in an embodiment, the second width W2 of the upper gate structure 60 is less than the first width W1 of the lower gate structure 40.

Referring to FIG. 12, in an embodiment, the second width W2 of the upper gate structure 60 is greater than the first width W1 of the lower gate structure 40.

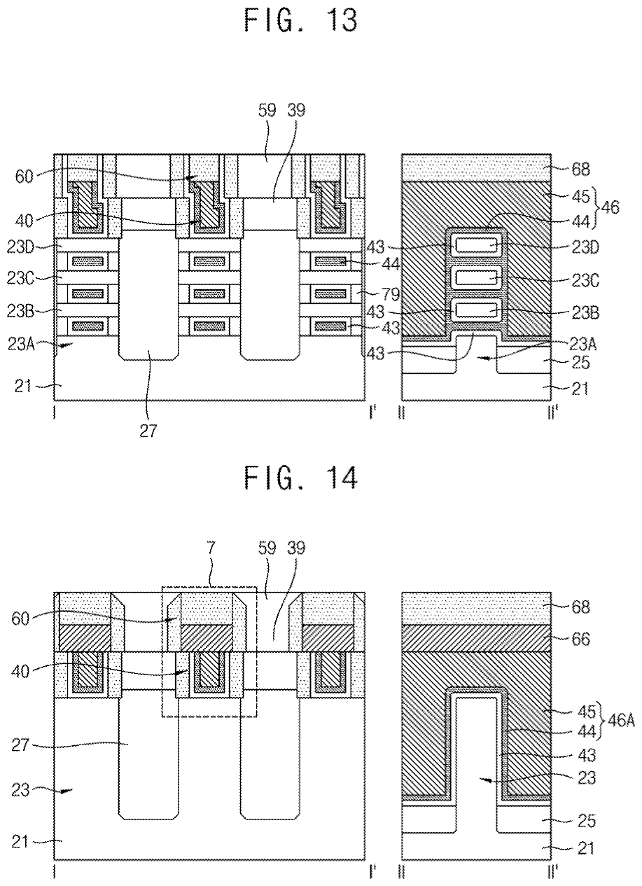

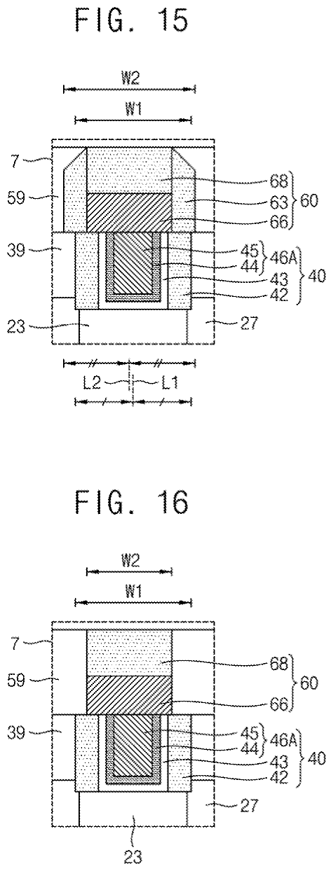

FIGS. 13 and 14 are cross-sectional views of semiconductor devices according to exemplary embodiments of the disclosure. FIGS. 15 to 17 are partial views of a portion 7 of FIG. 14. In an embodiment, FIGS. 13 and 14 are cross-sectional views taken along lines I-I′ and II-II′ in FIG. 18.

Referring to FIG. 13, in an embodiment, semiconductor devices according to exemplary embodiments of the disclosure include a multi-bridge channel transistor such as an MBCFET®. Semiconductor devices according to exemplary embodiments of the disclosure include a substrate 21, a plurality of active regions 23A, 23B, 23C and 24D, an element isolation layer 25, a plurality of source/drain regions 27, a first interlayer insulating layer 39, a plurality of gate structures 40 and 60, a second interlayer insulating layer 59, and a plurality of buried capping patterns 79. Each of the plurality of gate structures 40 and 60 includes a lower gate structure 40 and an upper gate structure 60. Each of the lower gate structure 40 and the upper gate structure 60 has a configuration similar to configurations described with reference to FIGS. 1 to 12.

In an embodiment, the plurality of active regions 23A, 23B, 23C and 23D include a first active region 23A, a second active region 23B, a third active region 23C, and a fourth active region 23D that are sequentially aligned in a vertical direction. The first active region 23A is defined on the substrate 21 by the element isolation layer 25. The first active region 23A, the second active region 23B, the third active region 23C, and the fourth active region 23D are spaced apart from one another. Side surfaces of the plurality of active regions 23A, 23B, 23C and 23D directly contact the plurality of source/drain regions 27.

In an embodiment, the lower gate structure 40 is disposed on the plurality of active regions 23A, 23B, 23C and 23D and crosses the plurality of active regions 23A, 23B, 23C and 23D, and surrounds a top surface, a bottom surface and side surfaces of at least one of the plurality of active regions 23A, 23B, 23C and 23D. In an embodiment, a first layer 44 of the gate electrode 46 extends on the element isolation layer 25 and covers the top surface and side surfaces of the first active region 23A. A gate dielectric layer 43 is disposed between the first layer 44 and the first active region 23A and between the first layer 44 and the element isolation layer 25. The first layer 44 surrounds the top surface, the bottom surface and the side surfaces of each of the second active region 23B, the third active region 23C and the fourth active region 23D. The gate dielectric layer 43 is disposed between the first layer 44 and the second active region 23B, between the first layer 44 and the third active region 23C and between the first layer 44 and the fourth active region 23D.

In an embodiment, the plurality of buried capping patterns 79 are disposed between the plurality of active regions 23A, 23B, 23C and 23D. The plurality of buried capping patterns 79 are disposed between the plurality of source/drain regions 27 and the first layer 44. The plurality of buried capping patterns 79 include at least two of Si, O, N, C, or B. For example, the plurality of buried capping patterns 79 include silicon nitride.

Referring to FIG. 14, in an embodiment, semiconductor devices according to exemplary embodiments of the disclosure include a substrate 21, an active region 23, an element isolation layer 25, a plurality of source/drain regions 27, a first interlayer insulating layer 39, a plurality of gate structures 40 and 60, and a second interlayer insulating layer 59. Each of the plurality of gate structures 40 and 60 includes a lower gate structure 40 and an upper gate structure 60.

Referring to FIG. 15, in an embodiment, the lower gate structure 40 includes a pair of lower spacers 42 that oppose each other, a gate dielectric layer 43, and a lower gate electrode 46A. The lower gate electrode 46A includes a first layer 44 and a second layer 45. The upper gate structure 60 includes a pair of upper spacers 63 that oppose each other, an upper gate electrode 66, and a capping layer 68.

Again referring to FIGS. 14 and 15, in an embodiment, top surfaces of the first interlayer insulating layer 39, the pair of lower spacers 42, the gate dielectric layer 43, and the lower gate electrode 46A are substantially coplanar.

In an embodiment, the upper gate electrode 66 vertically overlaps the lower gate electrode 46A. The capping layer 68 is disposed on the upper gate electrode 66. The upper gate electrode 66 and the capping layer 68 are disposed between the pair of upper spacers 63. Side surfaces of the upper gate electrode 66 and the capping layer 68 directly contact the pair of upper spacers 63. A second width W2 of the upper gate structure 60 is greater than a first width W1 of the lower gate structure 40. A second line L2 that passes the center of the upper gate structure 60 is parallel to a first line L1 that passes through the center of the lower gate structure 40. Top surfaces of the pair of upper spacers 63 are slanted with respect to top surfaces of the first interlayer insulating layer 39, the pair of lower spacers 42, the gate dielectric layer 43, and the lower gate electrode 46A. The slants of the top surfaces of the pair of upper spacers 63 are symmetric with respect to the second line L2.

Referring to FIG. 16, in an embodiment, the upper gate structure 60 includes an upper gate electrode 66 and a capping layer 68. The second width W2 of the upper gate structure 60 is less than the first width W1 of the lower gate structure 40. The pair of upper spacers 63 of FIG. 16 are omitted.

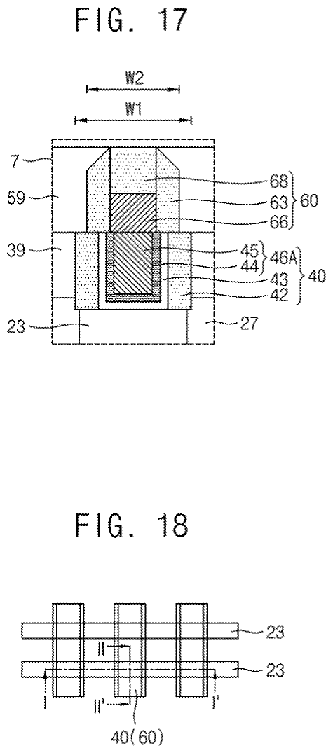

Referring to FIG. 17, in an embodiment, the upper gate structure 60 includes a pair of upper spacers 63 that oppose each other, an upper gate structure 66, and a capping layer 68. The second width W2 of the upper gate structure 60 is less than the first width W1 of the lower gate structure 40. The pair of upper spacers 63 have top surfaces similar to those of the upper spacers 63 shown in FIG. 15.

FIG. 18 is a layout of a semiconductor device according to exemplary embodiments of the disclosure.

Referring to FIG. 18, in an embodiment, semiconductor devices according to exemplary embodiments of the disclosure include a plurality of active regions 23 parallel to one another. A plurality of gate structures 40 and 60 that are parallel to each other are disposed that cross the plurality of active regions 23. The plurality of gate structures 40 and 60 extend in a direction substantially perpendicular to an extension direction of the active region 23. Each of the plurality of gate structures 40 and 60 include a lower gate structure 40 and an upper gate structure 60.

FIGS. 19 to 29 are cross-sectional views taken along lines I-I′ and II-II′ in FIG. 18 that illustrate methods of forming semiconductor devices according to exemplary embodiments of the disclosure.

Referring to FIGS. 18 and 19, in an embodiment, formation methods of semiconductor devices according to exemplary embodiments of the disclosure include forming, on a substrate 21, an element isolation layer 25 that defines an active region 23.

In an embodiment, the substrate 21 is a semiconductor substrate such as a silicon wafer or a silicon-on-insulator (SOI) wafer. For example, the substrate 21 includes a monocrystalline silicon layer that includes P-type impurities. The active region 23 is defined up to a predetermined depth from a top surface of the substrate 21 by the element isolation layer 25. The active region 23 includes a monocrystalline silicon layer that includes P-type or N-type impurities. In an embodiment, the active region 23 has a fin shape. A height of the active region 23 is greater than a horizontal width thereof.

In an embodiment, the element isolation layer 25 is an insulating layer formed using a shallow trench isolation (STI) method. The element isolation layer 25 includes one or more of silicon oxide, silicon nitride, silicon oxynitride, silicon boron nitride (SiBN), silicon carbon nitride (SiCN), low-k dielectrics, high-k dielectrics, or a combination thereof. Atop surface of the element isolation layer 25 is lower than an uppermost end of the active region 23. An upper portion of the active region 23 is exposed above the top surface of the element isolation layer 25. A top surface and side surfaces of the active region 23 are exposed above the top surface of the element isolation layer 25. Upper edges of the active region 23 are rounded.

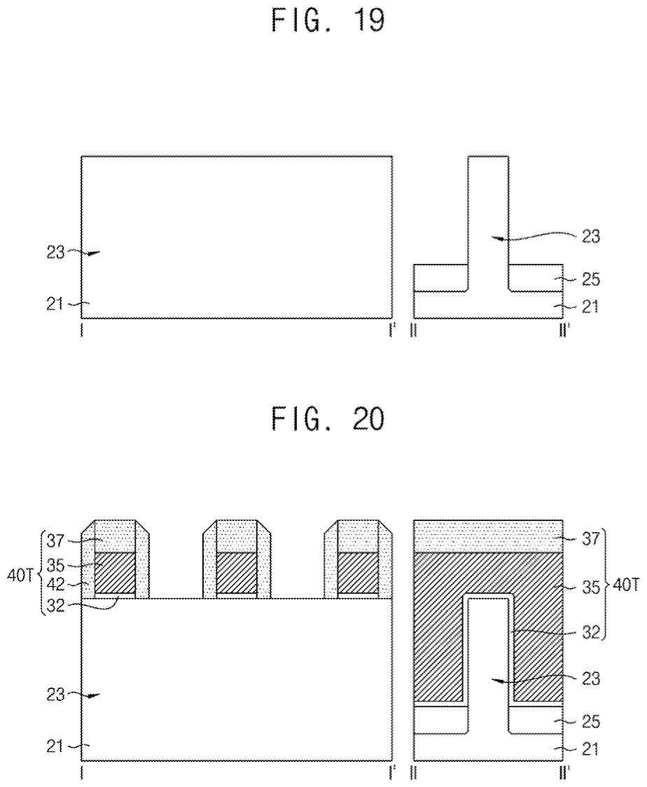

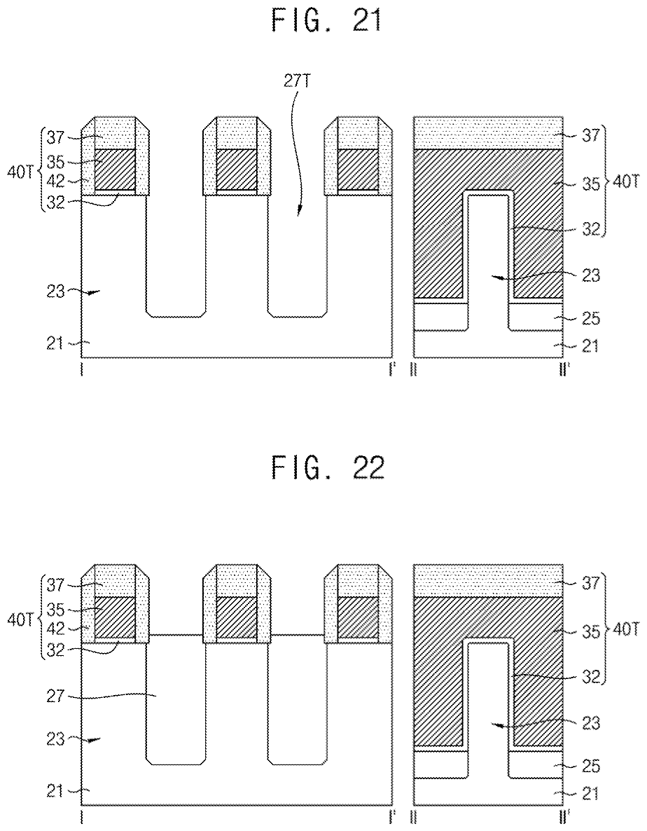

Referring to FIGS. 18 and 20, in an embodiment, a plurality of temporary lower gate structures 40T are formed that extend on the element isolation layer 25 and cross the active region 23. Formation of the plurality of temporary lower gate structures 40T includes a plurality of thin film formation processes and a patterning process. Each of the plurality of temporary lower gate structures 40T includes a buffer layer 32, a first sacrificial gate electrode 35, a first mask pattern 37, and a pair of lower spacers 42. The active region 23 is exposed between the plurality of temporary lower gate structures 40T.

In an embodiment, the buffer layer 32, the first sacrificial gate electrodes 35, and the first mask pattern 37 are sequentially stacked on the active region 23. The pair of lower spacers 42 are formed on side surfaces of the buffer layer 32, the first sacrificial gate electrode 35 and the first mask pattern 37. The buffer layer 32, the first sacrificial gate electrode 35 and the first mask pattern 37 are formed between the pair of lower spacers 42.

In an embodiment, the buffer layer 32 includes silicon oxide. The buffer layer 32 contacts the top surface and the side surfaces of the active region 23. The buffer layer 32 extends on the element isolation layer 25. The first sacrificial gate electrode 35 includes one or more of polysilicon, SiGe, or a combination thereof. The first sacrificial gate electrode 35 is formed on the buffer layer 32. The first sacrificial gate electrode 35 extends on the element isolation layer 25 and covers the top surface and side surfaces of the active region 23. The buffer layer 32 is interposed between the first sacrificial gate electrode 35 and the active region 23 and between the first sacrificial gate electrode 35 and the element isolation layer 25. A lowermost end of the first sacrificial gate electrode 35 is lower than the top surface of the active region 23.

In an embodiment, the first mask pattern 37 is formed on the first sacrificial gate electrode 35. The first mask pattern 37 includes silicon nitride.

In an embodiment, the pair of lower spacers 42 directly contacts the side surfaces of the buffer layer 32, the first sacrificial gate electrode 35 and the first mask pattern 37. The pair of lower spacers 42 includes a material that has etch selectivity with respect to the buffer layer 32 and the first sacrificial gate electrode 35. For example, the pair of lower spacers 42 includes silicon nitride. Each of the pair of lower spacers 42 may be a single layer or includes multiple layers.

Referring to FIGS. 18 and 21, in an embodiment, the active region 23 is etched using the plurality of temporary lower gate structure 40T as an etch mask, thereby forming a plurality of source/drain trenches 27T. To form the plurality of source/drain trenches 27T, an anisotropic etching process, an isotropic etching process, a directional etching process, or a combination thereof are applied. The plurality of source/drain trenches 27T are formed between the plurality of temporary lower gate structures 40T. For example, a pair of source/drain trenches 27T are formed in the active region 23 adjacent to opposite sides of one of the plurality of temporary lower gate structures 40T.

Referring to FIGS. 18 and 22, in an embodiment, a plurality of source/drain regions 27 are formed in the plurality of source/drain trenches 27T. Formation of the plurality of source/drain regions 27 includes a selective epitaxial growth process. The plurality of source/drain regions 27 include one of more of SiGe, SiC, Si, or a combination thereof. Each of the plurality of source/drain regions 27 protrudes above the top surface of the active region 23.

In an embodiment, the active region 23 includes a monocrystalline silicon that includes N-type impurities. The plurality of source/drain regions 27 include one or more of an SiGe layer that includes P-type impurities, an Si layer that includes P-type impurities, or a combination thereof.

In an embodiment, the active region 23 includes a monocrystalline silicon that includes P-type impurities. The plurality of source/drain regions 27 include one or more of an SiC layer that includes N-type impurities, an Si layer that includes N-type impurities, or a combination thereof.

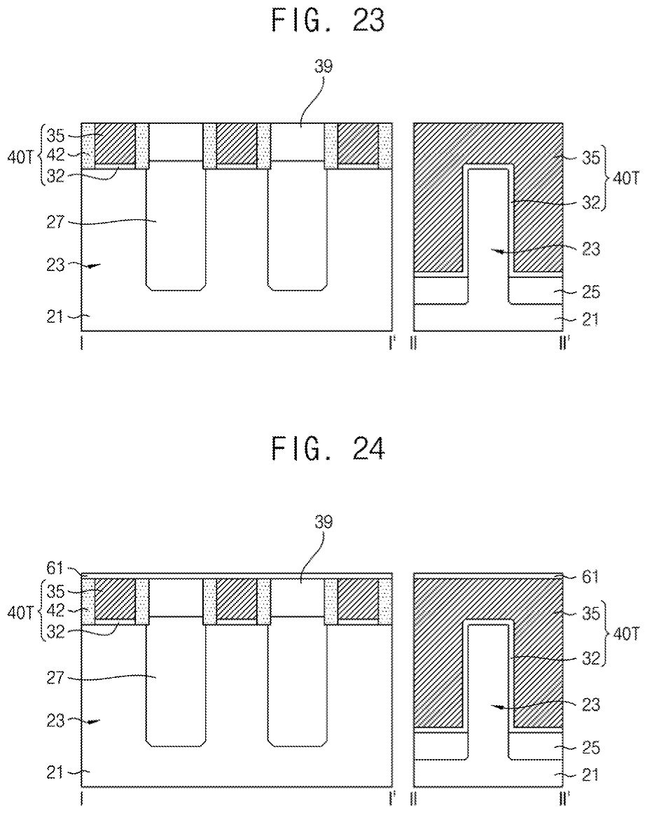

Referring to FIGS. 18 and 23, in an embodiment, a first interlayer insulating layer 39 is formed on the plurality of source/drain regions 27. The first interlayer insulating layer 39 may be a single layer or includes multiple layers. The first interlayer insulating layer 39 includes at least two of Si, O, N, C, or B. For example, the first interlayer insulating layer 39 includes one or more of silicon oxide, silicon nitride, silicon oxynitride, low-k dielectrics, high-k dielectrics, or a combination thereof.

In an embodiment, the first mask pattern 37 is removed, thereby exposing a top surface of the first sacrificial gate electrode 35. To remove the first mask pattern 37, a planarization process such as a chemical mechanical polishing (CMP) process, an etch-back process, or a combination thereof is applied. Top surfaces of the pair of lower spacers 42, the first sacrificial gate electrodes 35 and the first interlayer insulating layer 39 are exposed and are substantially coplanar.

Referring to FIGS. 18 and 24, in an embodiment, a first upper spacer 61 is formed on the pair of lower spacers 42, the first sacrificial gate electrode 35 and the first interlayer insulating layer 39. The first upper spacer 61 covers the top surfaces of the pair of lower spacers 42 and the first sacrificial gate electrode 35. The first upper spacer 61 directly contacts the top surfaces of the pair of lower spacers 42 and the first sacrificial gate electrode 35. The first upper spacer 61 includes a different material from the pair of lower spacers 42, the first sacrificial gate electrode 35 and the buffer layer 32. The first upper spacer 61 includes a material that has etch selectivity with respect to the buffer layer 32. The first upper spacer 61 includes one or more of silicon oxynitride, silicon oxycarbonitride (SiOCN), silicon boron nitride (SiBN), silicon carbon nitride (SiCN), hafnium oxide (HfO), hafnium silicate (HfSiO), aluminum oxide (AlO), or a combination thereof.

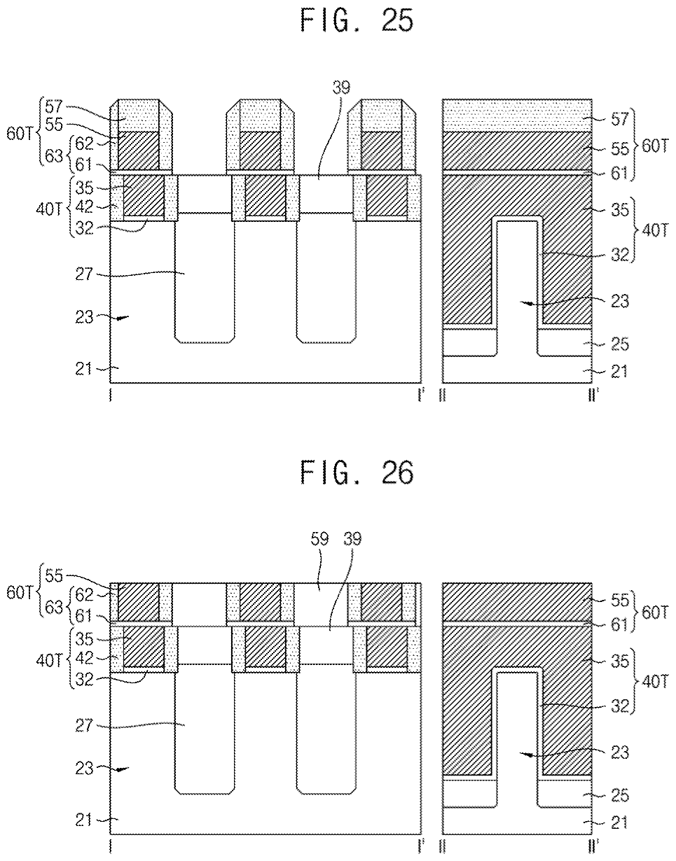

Referring to FIGS. 18 and 25, in an embodiment, a plurality of temporary upper gate structures 60T is formed on the plurality of temporary lower gate structures 40T and the first interlayer insulating layer 39. Each of the plurality of temporary upper gate structures 60T has a horizontal width that differs from the horizontal width of each of the plurality of temporary lower gate structures 40T. Each of the plurality of temporary upper gate structures 60T partially overlaps one of a corresponding temporary lower gate structures 40T. The center of each of the plurality of temporary upper gate structures 60T is offset from the center of the corresponding temporary lower gate structure 60T.

In an embodiment, formation of the plurality of temporary upper gate structures 60T includes a plurality of thin film formation processes and a patterning process. Each of the plurality of temporary upper gate structures 60T includes a pair of upper spacers 63, a second sacrificial gate electrode 55, and a second mask pattern 57. The pair of upper spacers 63 includes the first upper spacer 61 and a pair of second upper spacers 62. The second sacrificial gate electrode 55 and the second mask pattern 57 are sequentially stacked on the first upper spacer 61. The second sacrificial gate electrode 55 and the second mask pattern 57 are formed between the pair of second upper spacers 62.

In an embodiment, the second sacrificial gate electrode 55 includes a material that differs from that of the pair of upper spacers 63. In an embodiment, the second sacrificial gate electrode 55 includes the same material as the first sacrificial gate electrode 35. The second sacrificial gate electrode 55 includes one or more of polysilicon, SiGe, or a combination thereof. In an embodiment, the second sacrificial gate electrode 55 includes a material that differs from that of the first sacrificial gate electrode 35. For example, the first sacrificial gate electrode 35 includes polysilicon, whereas the second sacrificial gate electrode 55 includes SiGe.

In an embodiment, the second mask pattern 57 includes silicon nitride. Each of the pair of second upper spacers 62 may be a single layer or includes multiple layers. The pair of second upper spacers 62 includes a material that differs from that of the first upper spacer 61. The pair of second upper spacers 62 includes the same material as the pair of first lower spacers 42. The pair of second upper spacers 62 includes silicon nitride. The pair of second upper spacers 62 directly contacts a top surface of the first upper spacer 61.

Referring to FIGS. 18 and 26, in an embodiment, a second interlayer insulating layer 59 is formed on the first interlayer insulating layer 39. The second interlayer insulating layer 59 may be a single layer or includes multiple layers. The second interlayer insulating layer 59 includes at least two of Si, O, N, C, or B. For example, the second interlayer insulating layer 59 includes one or more of silicon oxide, silicon nitride, silicon oxynitride, low-k dielectrics, high-k dielectrics, or a combination thereof.

In an embodiment, the second mask pattern 57 is removed, thereby exposing a top surface of the second sacrificial gate electrode 55. To remove the second mask pattern 57, a planarization process such as a chemical mechanical polishing (CMP) process, an etch-back process, or a combination thereof may be applied. Top surfaces of the pair of second upper spacers 62, the second sacrificial gate electrode 55 and the second interlayer insulating layer 59 are exposed and are substantially coplanar.

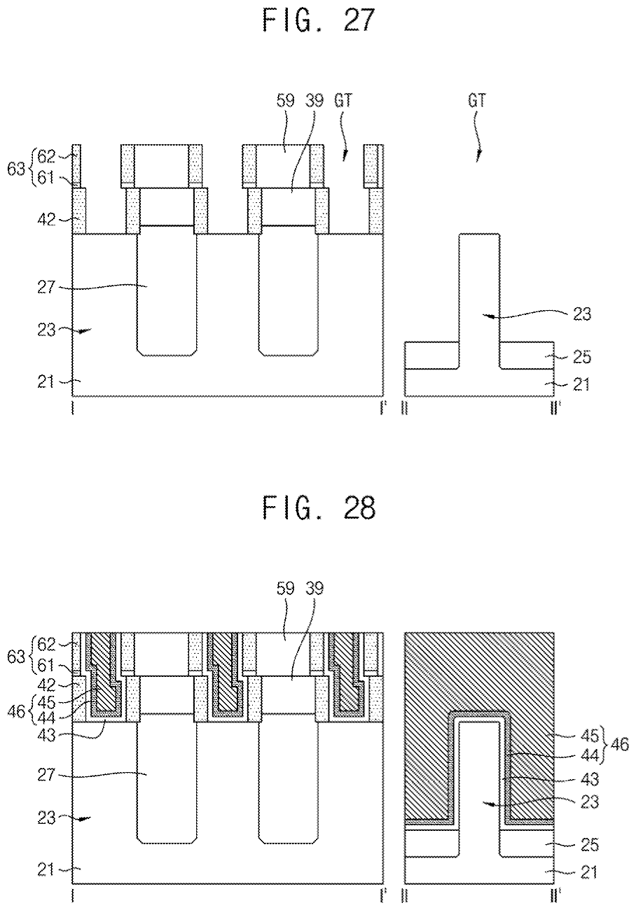

Referring to FIGS. 18 and 27, in an embodiment, the second sacrificial gate electrode 55, the first upper spacer 61, the first sacrificial gate electrode 35, and the buffer layer 32 are removed, thereby forming a plurality of gate trenches GT. The first upper spacer 61 is preserved under the second upper spacer 62. The top surface and the side surfaces of the active region 23 are exposed in the plurality of gate trenches GT. The top surface of the element isolation layer 25 is exposed in the plurality of gate trenches GT. The pair of lower spacers 42 and the pair of upper spacers 63 are exposed in the plurality of gate trenches GT.

Referring to FIGS. 18 and 28, in an embodiment, a gate dielectric layer 43 is formed in the plurality of gate trenches GT. A plurality of gate electrodes 46 are formed on the gate dielectric layer 43 in the plurality of gate trenches GT. Each of the plurality of gate electrodes 46 includes a first layer 44 and a second layer 45.

In an embodiment, formation of the gate dielectric layer 43 and the plurality of gate electrodes 46 includes a plurality of thin film formation processes and a planarization process. The planarization process includes one or more of a chemical mechanical polishing (CMP) process, an etch-back process, or a combination thereof. Top surfaces of the second interlayer insulating layer 59, the second upper spacer 62, the gate dielectric layer 43, the first layer 44, the second layer 45 are exposed and are substantially coplanar.

In an embodiment, the gate dielectric layer 43 may be a single layer or includes multiple layers. The gate dielectric layer 43 includes one or more of silicon oxide, silicon nitride, silicon oxynitride, high-k dielectrics, or a combination thereof In an embodiment, the gate dielectric layer 43 includes a silicon oxide layer, an LaO layer on the silicon oxide layer, and a high-k dielectric layer, such as an HfO layer, on the LaO layer.

In an embodiment, the plurality of gate electrodes 46 include one or more of a metal, a metal nitride, a metal oxide, a metal silicide, conductive carbon, polysilicon, or a combination thereof. In an embodiment, the first layer 44 includes a work function metal layer. The first layer 44 includes one or more of Ti, TiN, Ta, TaN, or a combination thereof. The second layer 45 includes one or more of W, WN, Ti, TiN, Ta, TaN, Ru, or a combination thereof. The plurality of gate electrodes 46 correspond to a replacement metal gate electrode.

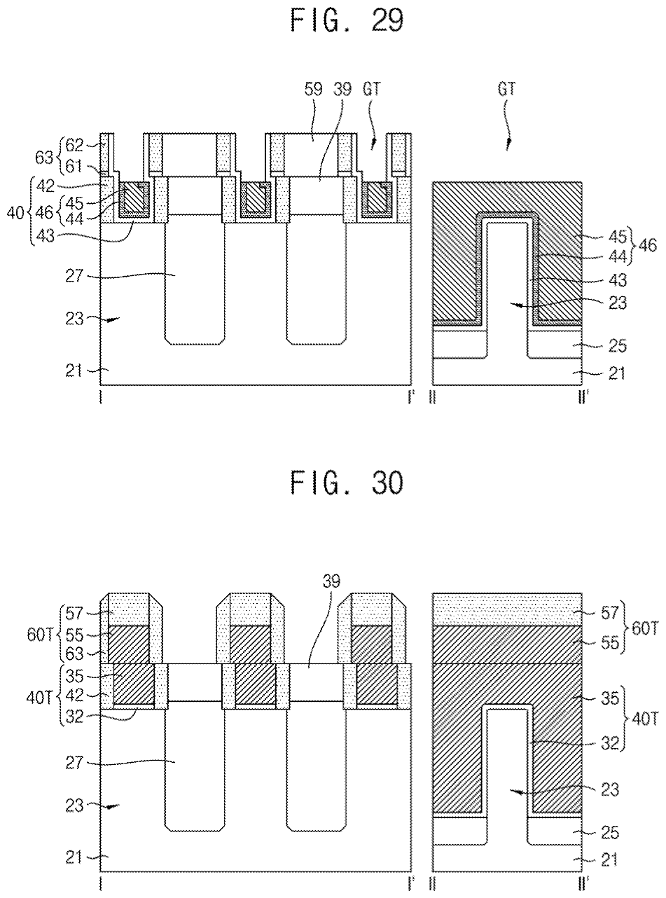

Referring to FIGS. 18 and 29, in an embodiment, the plurality of gate electrodes 46 are partially removed, thereby exposing upper portions of the plurality of gate trenches GT. Top surfaces of the plurality of gate electrodes 46 are located at a level that differs from that of a plane of an interface between the pair of lower spacers 42 and the pair of upper spacers 63. For example, the top surfaces of the plurality of gate electrodes 46 are located at a lower level than the plane of the interface between the pair of lower spacers 42 and the pair of upper spacers 63.

Referring again to FIGS. 18 and 1, in an embodiment, a capping layer 68 is formed on the plurality of gate electrodes 46. The capping layer 68 includes at least two of Si, O, N, C, or B. For example, the capping layer 68 includes one or more of silicon oxide, silicon nitride, silicon oxynitride, low-k dielectrics, high-k dielectrics, or a combination thereof. For example, the capping layer 68 includes silicon nitride. Formation of the capping layer 68 includes a planarization process. The planarization process includes one or more of a chemical mechanical polishing (CMP) process, an etch-back process, or a combination thereof. The top surfaces of the second interlayer insulating layer 59, the second upper spacer 62, the gate dielectric layer 43 and the capping layer 68 are exposed and are substantially coplanar.

FIGS. 30 to 34 are cross-sectional views taken along lines I-I′ and II-II′ in FIG. 18 that illustrate formation methods of semiconductor devices according to exemplary embodiments of the disclosure.

Referring to FIGS. 18 and 30, in an embodiment, a plurality of temporary upper gate structures 60T are formed on a plurality of temporary lower gate structures 40T and a first interlayer insulating layer 39. Each of the plurality of temporary upper gate structures 60T includes a pair of upper spacers 63, a second sacrificial gate electrode 55, and a second mask pattern 57. The second sacrificial gate electrode 55 and the second mask pattern 57 are sequentially stacked between the pair of upper spacers 63.

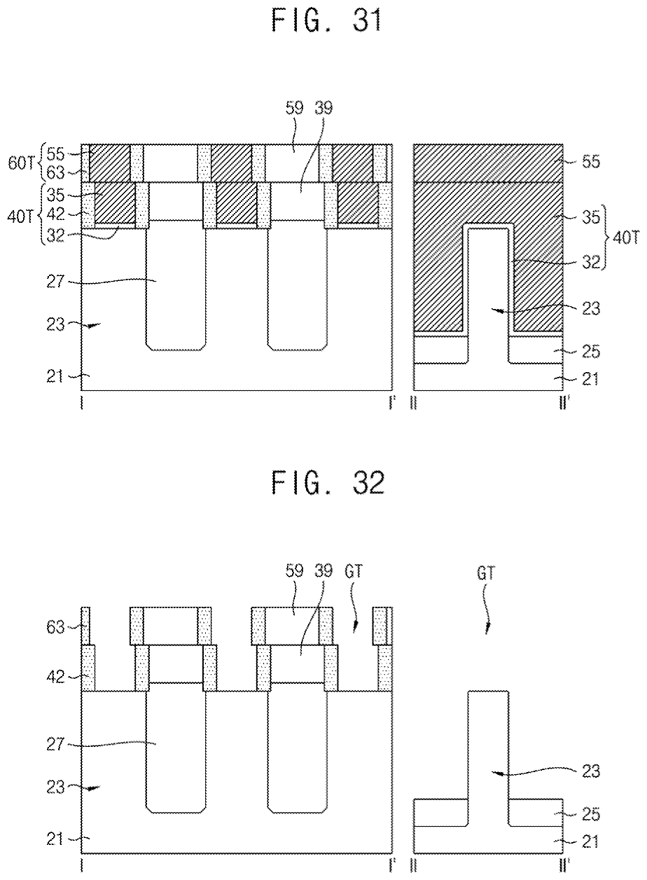

Referring to FIGS. 18 and 31, in an embodiment, a second interlayer insulating layer 59 is formed on the first interlayer insulating layer 39. The second mask pattern 57 is removed, thereby exposing a top surface of the second sacrificial gate electrode 55. Top surfaces of the pair of upper spacers 63, the second sacrificial gate electrode 55 and the second interlayer insulating layer 59 are exposed and are substantially coplanar.

Referring to FIGS. 18 and 32, in an embodiment, the second sacrificial gate electrode 55, the first sacrificial gate electrode 35, and a buffer layer 32 may be removed, thereby forming a plurality of gate trenches GT. The pair of lower spacers 42 and the pair of upper spacers 63 are exposed in the plurality of gate trenches GT.

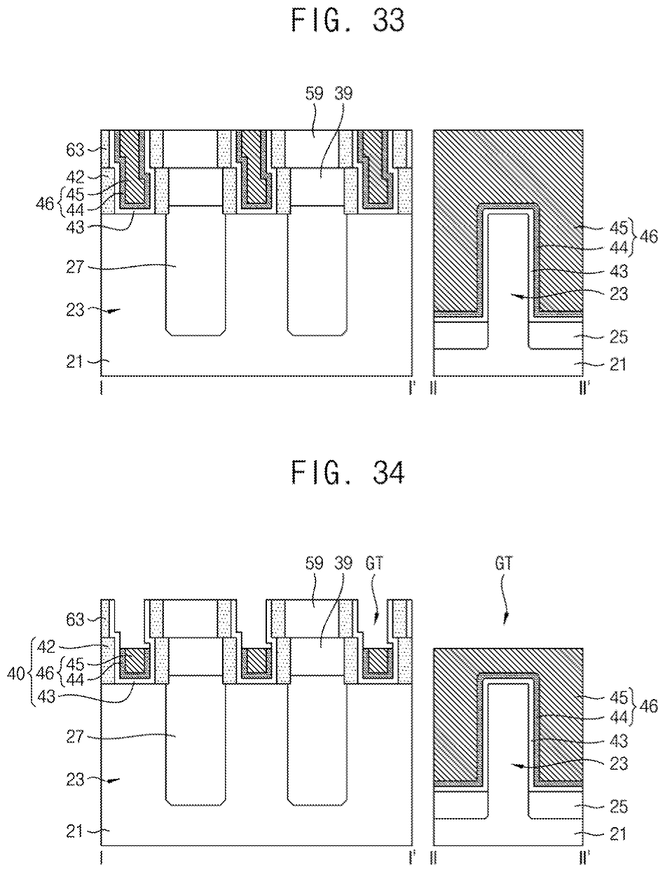

Referring to FIGS. 18 and 33, in an embodiment, a gate dielectric layer 43 is formed in the plurality of gate trenches GT. A plurality of gate electrodes 46 are formed on the gate dielectric layer 43 in the plurality of gate trenches GT. Each of the plurality of gate electrodes 46 includes a first layer 44 and a second layer 45.

Referring to FIGS. 18 and 34, in an embodiment, the plurality of gate electrodes 46 are partially removed, thereby exposing upper portions of the plurality of gate trenches GT. Top surfaces of the plurality of gate electrodes 46 are located at a level that differs from that of a plane of an interface between the pair of lower spacers 42 and the pair of upper spacers 63.

Referring again to FIGS. 18 and 9, a capping layer 68 is formed on the plurality of gate electrodes 46. The top surfaces of the second interlayer insulating layer 59, the pair of upper spacers 63, the gate dielectric layer 43 and the capping layer 68 are exposed and are substantially coplanar.

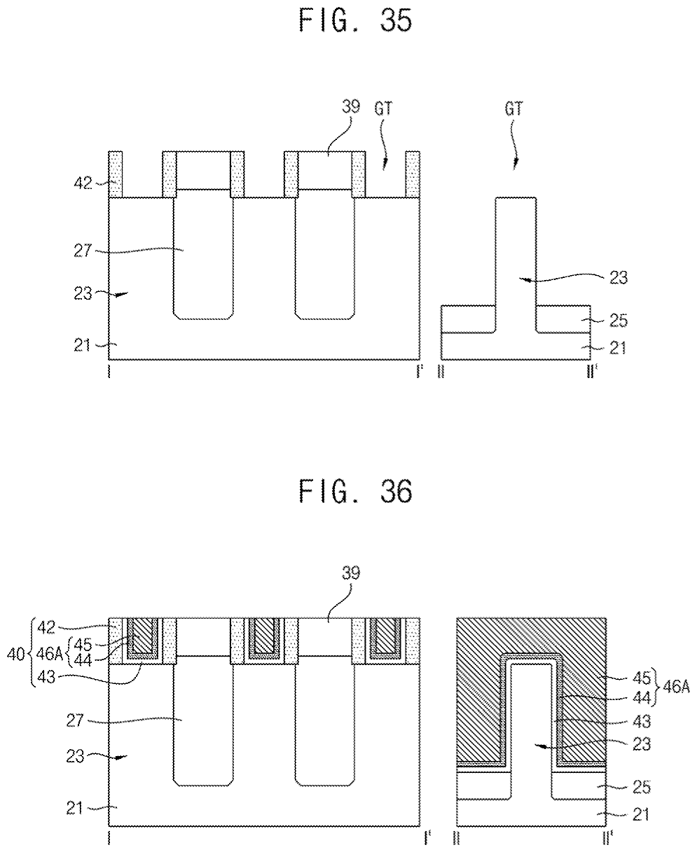

FIGS. 35 to 39 are cross-sectional views taken along lines I-I′ and II-II′ in FIG. 18 that illustrate formation methods of semiconductor devices according to exemplary embodiments of the disclosure.

Referring to FIGS. 18 and 35, a first interlayer insulating layer 39 is formed on a plurality of source/drain regions 27. The first sacrificial gate electrode 35 of FIG. 23 and the buffer layer 32 are removed, thereby forming a plurality of gate trenches GT. A top surface and side surfaces of an active region 23 are exposed in the plurality of gate trenches GT. A pair of lower spacers 42 are exposed in the plurality of gate trenches GT.

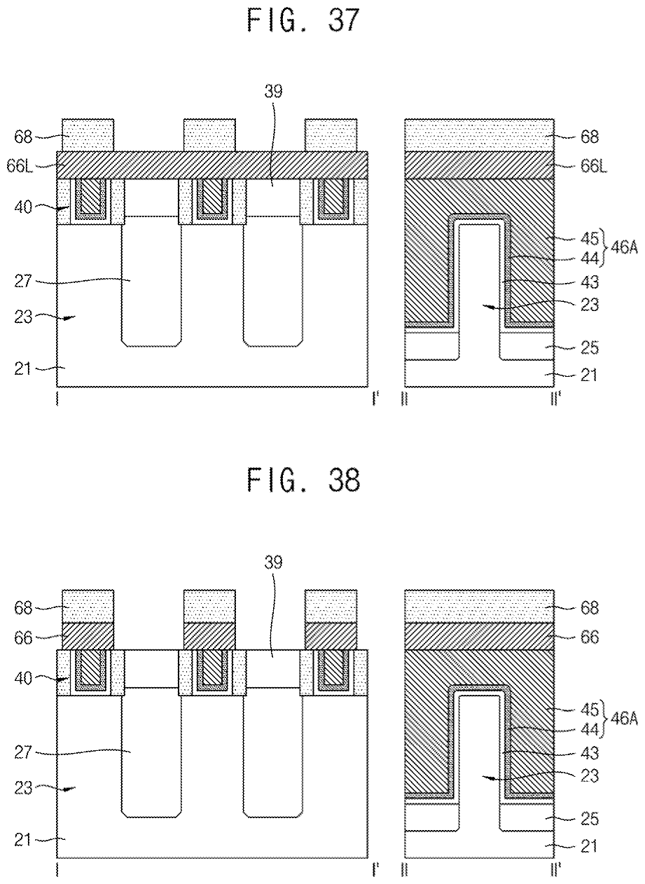

Referring to FIGS. 18 and 36, in an embodiment, a gate dielectric layer 43 is formed in the plurality of gate trenches GT. A plurality of lower gate electrodes 46A are formed on the gate dielectric layer 43 in the plurality of gate trenches GT. Each of the plurality of lower gate electrodes 46A includes a first layer 44 and a second layer 45. Top surfaces of the first interlayer insulating layer 39, the gate dielectric layer 43 and the plurality of lower gate electrodes 46A are exposed and are substantially coplanar.

Referring to FIGS. 18 and 37, in an embodiment, an upper gate conductive layer 66L is formed on the first interlayer insulating layer 39, the gate dielectric layer 43, and the plurality of lower gate electrodes 46A. A capping layer 68 is formed on the upper gate conductive layer 66L. The upper gate conductive layer 66L includes one or more of a metal, a metal nitride, a metal oxide, a metal silicide, conductive carbon, polysilicon, or a combination thereof. In an embodiment, the upper gate conductive layer 66L includes one or more of W, WN, Ti, TiN, Ta, TaN, Ru, or a combination thereof.

Referring to FIGS. 18 and 38, in an embodiment, the upper gate conductive layer 66L is partially removed using the capping layer 68 as an etch mask, thereby forming a plurality of upper gate electrodes 66.

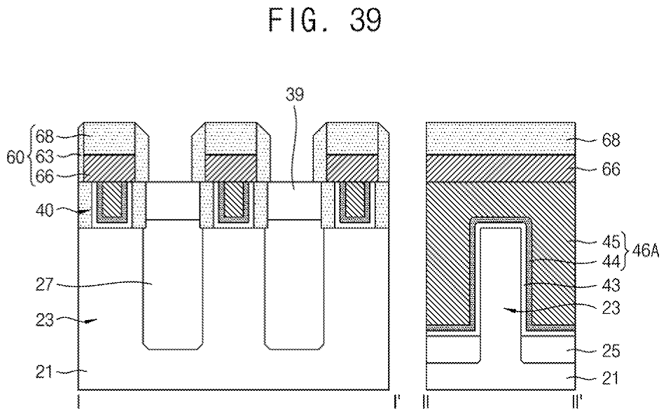

Referring to FIGS. 18 and 39, in an embodiment, a plurality of upper spacers 63 are formed on side surfaces of the capping layer 68 and the plurality of upper gate electrodes 66.

Again referring to FIGS. 18 and 14, a second interlayer insulating layer 59 is formed on the first interlayer insulating layer 39. The plurality of upper spacers 63, the plurality of upper gate electrodes 66, and the capping layer 68 form a plurality of upper gate structures 60. The second interlayer insulating layer 59 is preserved between the upper gate structures 60. Top surfaces of the second interlayer insulating layer 59 and the plurality of upper gate structures 60 are substantially coplanar.

In accordance with exemplary embodiments of the disclosure, an upper gate structure is provided that is disposed on a lower gate structure while having a width that differs from that of the lower gate structure. The center of the upper gate structure is offset from the center of the lower gate structure. Semiconductor devices having excellent electrical characteristics and that can be efficiently mass produced are realized.

While embodiments of the disclosure have been described with reference to the accompanying drawings, it should be understood by those skilled in the art that various modifications may be made without departing from the scope of embodiments of the disclosure and without changing features thereof. Therefore, above-described embodiments should be considered in a descriptive sense only and not for purposes of limitation.

1. A semiconductor device, comprising:
an active region defined on a substrate;
a lower gate structure disposed on the active region, wherein the lower gate structure crosses the active region;
an upper gate structure disposed on the lower gate structure wherein a width of the upper gate structure differs from a width of the lower gate structure; and
a pair of source/drain regions disposed in the active region adjacent opposite sides of the lower gate structure,
wherein a center of the upper gate structure is offset from center of the lower gate structure.

2. The semiconductor device according to claim 1, wherein:
the lower gate structure comprises
a pair of lower spacers that oppose each other, and
a gate electrode between the pair of lower spacers;
the upper gate structure comprises
a pair of upper spacers disposed on the pair of lower spacers and that oppose each other, and
a capping layer disposed on the gate electrode bet ween the pair of upper spacers; and
side surfaces of the pair of upper spacers are not aligned with side surfaces of the pair of lower spacers.

3. The semiconductor device according to claim 2, wherein an interface between the gate electrode and the capping layer is spaced apart from a plane of an interface between the pair of lower spacers and the pair of upper spacers.

4. The semiconductor device according to claim 3, wherein:
the capping layer extends between the pair of lower spacers; and
a lowermost end of the capping layer is closer to a top surface of the substrate than an uppermost end of the pair of lower spacers.

5. The semiconductor device according to claim 4, wherein a distance between the plane of the interface between the pair of lower spacers and the pair of upper spacers and the lowermost end of the capping layer is less than 0.2 times a vertical thickness of the pair of lower spacers.

6. The semiconductor device according to claim 3, wherein:
the gate electrode extends between die pair of upper spacers; and
a lowermost end of the capping layer is farther from a top surface of the substrate than a lowermost end of the pair of upper spacers.

7. The semiconductor device according to claim 2, wherein:
each of the pair of upper spacers comprises
a first upper spacer, and
a second upper spacer disposed on the first upper spacer; and
the first upper spacer is disposed between the pair of lower spacers and the second upper spacer.

8. The semiconductor device according to claim 7, wherein:
a horizontal width of the first upper sparer is greater than a vertical height of the first upper spacer; and
a vertical height of the second upper spacer is greater than a horizontal width of the second upper spacer.

9. The semiconductor device according to claim 7, wherein the first upper spacer comprises a material that differs from materials of the pair of lower spacers and the second upper spacer.

10. The semiconductor device according to claim 2, wherein the lower gate structure further comprises a gate dielectric layer interposed between the substrate and the gate electrode.

11. The semiconductor device according to claim 10, wherein the gate dielectric layer extends between the gate electrode and the pair of lower spacers.

12. The semiconductor device according to claim 1, wherein a horizontal width of the upper gate structure is less than a horizontal width of the lower gate structure.

13. The semiconductor device according to claim 1, wherein a horizontal width of the upper gate structure is greater than a horizontal width of the lower gate structure.

14. A semiconductor device, comprising:
a plurality of active regions that are vertically aligned on a substrate;
a lower gate structure disposed on the plurality of active regions, wherein the lower gate structure crosses the plurality of active regions and surrounds a top surface, a bottom surface and side surfaces of at least one of the plurality of active regions;
an upper gate structure disposed on the lower gate structure wherein a width of the upper gate structure differs from a width of the lower gate structure; and
a pair of source/drain regions disposed adjacent to opposite sides of the lower gate structure and that contact the plurality of active regions,
wherein a center of the upper gate structure is offset from a center of the lower gate structure.

15. A semiconductor device, comprising:
an active region defined a substrate;
a lower gate structure disposed on the active region, wherein the lower gate structure crosses the active region;
an upper gate structure disposed on the lower gate structure wherein a width of the upper gate structure differs from a width of the lower gate structure; and
a pair of source/drain regions disposed in the active region adjacent to opposite sides of the lower gate structure,
wherein a center of the upper gate structure is offset from a center of the lower gate structure,
wherein the lower gate structure comprises
a pair of lower spacers that oppose each other, and
a lower gate electrode interposed between the pair of lower spacers; and
the upper gate structure comprises
an upper gate electrode disposed on the lower gate electrode, and
a capping layer disposed on the upper gate electrode.

16. The semiconductor device according to claim 15, wherein top surfaces of the pair of lower spacers and the lower gate electrode are substantially coplanar.

17. The semiconductor device according to claim 16, wherein:
the lower gate structure further comprises
a gate dielectric layer interposed between the substrate and the lower gate electrode, wherein
the gate dielectric layer extends between the lower gate electrode and the pair of lower spacers.

18. The semiconductor device according to claim 15, further comprising:
a pair of upper spacers disposed on the pair of lower spacers and that oppose each other,
wherein the upper gate electrode and the capping layer are disposed between the pair of upper spacers.

19. The semiconductor device according to claim 18, wherein the upper gate electrode and the capping layer directly contact the pair of upper spacers.

20. The semiconductor device according to claim 15, wherein a horizontal width of the upper gate structure is less than a horizontal width of the lower gate structure.

21-25. (canceled)
